(19) United States
(12) Patent Application Publication
(10) Pub. No.: US 2026/0150505 A1
(43) Pub. Date: May 28, 2026

(54) Display Device

(71) Applicant: LG Display Co., Ltd., Seoul (KR)

(72) Inventor: Beongho Lee, Paju-si (KR)

(21) Appl. No.: 19/097,485

(22) Filed: Apr. 1, 2025

(30) Foreign Application Priority Data
Nov. 25, 2024 (KR) 10-2024-0169650

(51) Int. Cl. H10K 59/122; H10K 59/80

(52) U.S. Cl. CPC H10K 59/122; H10K 59/80515

(57) ABSTRACT

A display device includes a substrate including a display area having sub-pixels including a first, second, and third sub-pixels, a first electrode in each of the sub-pixels on the substrate, a bank on the first electrode, positioned at a boundary between adjacent sub-pixels, covering a peripheral portion of an upper surface of the first electrode, and including a first bank on the first electrode and a second bank on the first bank, and an organic layer on the first electrode and the bank, and extending across the sub-pixels, wherein the first bank includes an overlapping portion overlapping with the second bank, and a first exposed portion exposed by the second bank and including a side surface, and wherein the bank includes a groove portion that is recessed from an upper surface of the bank, and a separation portion surrounding the first exposed portion in a plan view.

### CROSS REFERENCE TO RELATED APPLICATION

The present application claims priority to Republic of Korea Patent Application No. 10-2024-0169650, filed on Nov. 25, 2024, which is hereby incorporated by reference in its entirety.

### BACKGROUND

### Field of Technology

This specification relates to a display device.

### Description of the Related Art

With the advancement of the information society, there is an increasing demand for display devices that can show images, and various types of display devices such as liquid crystal display (LCD) devices and organic light emitting diode (OLED) displays are being utilized.

The display device includes a plurality of pixels and is equipped with a plurality of switching elements to drive and control the pixels.

### SUMMARY

It is an object of the embodiments of this specification to provide a display device capable of improving lateral leakage current between adjacent sub-pixels.

It is another object of the embodiments of this specification to provide a display device capable of absorbing external light incident beneath a bank.

It is another object of the embodiments of this specification to provide a display device capable of improving the spreadability of a second encapsulation layer (or an organic encapsulation layer).

It is still another object of the embodiments of this specification to provide a low-reflection display device.

The objects of this specification are not limited to the foregoing, and other objects may be inferred from the following embodiments.

In order to accomplish the above object, a display device according to an embodiment includes a substrate including a display area having a plurality of sub-pixels including a first sub-pixel, a second sub-pixel, and a third sub-pixel, and a non-display area surrounding the display area, a first electrode disposed in each of the sub-pixels on the substrate, a bank disposed on the first electrode, positioned at a boundary between adjacent sub-pixels, covering a peripheral portion of an upper surface of the first electrode, and including a first bank on the first electrode and a second bank on the first bank, and an organic layer disposed on the first electrode and the bank, and extending across the plurality of sub-pixels, wherein the first bank includes an overlapping portion overlapping with the second bank, and a first exposed portion exposed by the second bank and including a side surface, and wherein the bank includes a groove portion formed to be recessed from an upper surface of the bank, and a separation portion surrounding the first exposed portion in a plan view.

In order to accomplish the above objects, a display device according to an embodiment includes a substrate including a display area having a plurality of sub-pixels including a first sub-pixel, a second sub-pixel, and a third sub-pixel, and a non-display area surrounding the display area, a first electrode disposed in each of the sub-pixels on the substrate, a bank disposed on the first electrode, positioned at a boundary between adjacent sub-pixels, covering a peripheral portion of an upper surface of the first electrode, and including a first bank on the first electrode and a second bank on the first bank, a separation portion on an upper surface of the bank between adjacent sub-pixels, and an organic layer disposed on the first electrode, the bank, and the separation portion, and extending across the plurality of sub-pixels, wherein the first bank includes an overlapping portion overlapping with the second bank, and a first exposed portion exposed by the second bank and including a side surface, and wherein the bank includes a groove portion formed to be recessed from the upper surface of the bank.

The specific details of other embodiments are included in the detailed description and drawings.

### BRIEF DESCRIPTION OF THE DRAWINGS

FIG. 1 is a plan view of a display device according to an embodiment;

FIG. 2 is a cross-sectional view of the display panel of FIG. 1 in a bent state according to an embodiment;

FIG. 3 is a cross-sectional view taken along line A-A′ of FIG. 1 according to an embodiment;

FIG. 4 is a detailed cross-sectional view of the lighting-emitting layer of FIG. 3 according to an embodiment;

FIG. 5 is a detailed cross-sectional view of the light-emitting layer according to an alternative embodiment;

FIG. 6 is a plan view illustrating the arrangement of sub-pixels in the display area of FIG. 1 according to an embodiment;

FIG. 7 is a cross-sectional view taken along line B-B′ of FIG. 6 according to an embodiment;

FIG. 8 is a schematic diagram illustrating the improvement in the spreadability of the second encapsulation layer due to the groove portion according to FIG. 7 according to an embodiment;

FIG. 9 is a cross-sectional view of a display device according to another embodiment;

FIG. 10 is a plan view illustrating the arrangement of sub-pixels in a display area according to another embodiment;

FIG. 11 is a plan view illustrating the arrangement of sub-pixels in a display area according to another embodiment;

FIG. 12 is a plan view illustrating the arrangement of sub-pixels in a display area according to another embodiment;

FIG. 13 is a plan view illustrating the arrangement of sub-pixels in a display area according to another embodiment;

FIG. 14 is a cross-sectional view taken along line C-C′ of FIG. 13 according to an embodiment;

FIG. 15 is a plan view illustrating the arrangement of sub-pixels in a display area according to another embodiment;

FIG. 16 is a cross-sectional view taken along line D-D′ of FIG. 15 according to an embodiment;

FIG. 17 is a cross-sectional view of a display device according to another embodiment;

FIG. 18 is a perspective view of a display device according to another embodiment; and

FIG. 19 is a cross-sectional view taken along line E-E′ of FIG. 18 according to an embodiment.

### DETAILED DESCRIPTION

Hereinafter, embodiments will be described with reference to accompanying drawings.

The same reference numerals refer to the same components. Additionally, in the drawings, the thickness, proportions, and dimensions of components may be exaggerated for effective explanation of the technical content. Although depicted in a scale different from their actual scale for the convenience of explanation, the components are not limited to the scale shown in the drawing.

In the specification, when a component (or area, layer, part, etc.) is mentioned as being “on top of,” “connected to,” or “coupled to” another component, it means that it may be directly connected/coupled to the other component, or a third component may be placed between them.

The expression “and/or” is taken to include one or more combinations that can be defined by associated components.

The terms “first,” “second,” etc. are used to describe various components, but the components should not be limited by these terms. The terms are used only for distinguishing one component from another component. For example, a first component may be referred to as a second component and, similarly, the second component may be referred to as the first component, without departing from the scope of the embodiments. The singular forms are intended to include the plural forms as well unless the context clearly indicates otherwise.

The terms such as “below,” “lower,” “above,” “upper,” etc. are used to describe the relationship of components depicted in the drawings. The terms are relative concepts and are described based on the direction indicated on the drawing. For example, unless explicitly stated with terms such as “directly” or “immediately,” one or more other components may be positioned between two described components. Spatially relative terms such as “below,” “beneath,” “lower,” “above,” and “upper” may be used to facilitate the description of the relationship between one component or element and another, as illustrated in the drawings. These spatially relative terms should be understood to include different orientations of a component during use or operation, in addition to the orientation shown in the drawings. For instance, if a component shown in the drawings is flipped, a component described as being “below” or “beneath” another component may then be positioned “above” that component. Accordingly, the term “below,” for example, may encompass both upward and downward directions.

It will be further understood that the terms “comprises,” “has,” and the like are intended to specify the presence of stated features, numbers, steps, operations, components, parts, or a combination thereof but are not intended to preclude the presence or possibility of one or more other features, numbers, steps, operations, components, parts, or combinations thereof.

The various features of the embodiments of the disclosure can combined or assembled together, either partially or entirely, in a technically diverse manner, and each embodiment can be independently implemented or in conjunction with related embodiments.

Hereinafter, the display devices according to the embodiments of this specification will be described with reference to the accompanying drawings.

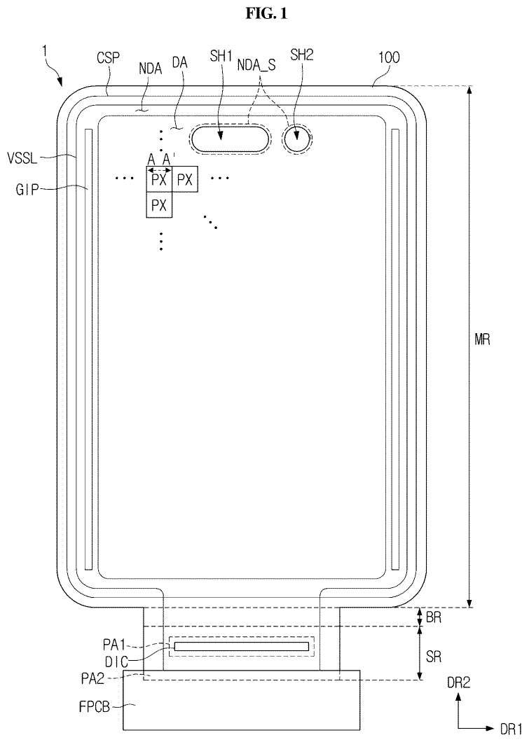

FIG. 1 is a plan view of a display device according to an embodiment;

Referring to FIG. 1, a display device 1 according to an embodiment may include a display panel 100. The display panel 100 may include a display area DA including a plurality of pixels PX and a non-display area NDA surrounding the display area DA. The display area DA may have a rectangular planar shape. However, the display area DA is not limited thereto and may have a square, circular, elliptical, or other polygonal planar shape. For example, the display area DA may have a rounded rectangular shape, but it is not limited thereto and may also be a rectangular shape with sharp corners.

In the embodiments, the first direction DR1 and the second direction DR2 are different directions that intersect each other, for example, directions that intersect perpendicularly in a plan view. In FIG. 1, the first direction DR1 generally corresponds to the extension direction of the short sides of the display panel 100, and the second direction DR2 may correspond to the extension direction of the long sides of the display panel 100. However, the directions mentioned in the embodiments should be understood as relative directions, and the embodiments are not limited to the directions mentioned.

The display area DA may include short sides extending along the first direction DR1 and long sides extending along the second direction DR2. The non-display area NDA may surround the display area DA. The non-display area NDA may be disposed on one side and the other side of the display area DA in the first direction DR1 and on one side and the other side of the display area DA in the second direction DR2.

The display panel 100 may further include sensor non-display areas NDA_S and sensor holes SH surrounded by the sensor non-display areas NDA_S. The sensor holes SH1 and SH2 may be surrounded by the display area DA in a plan view. The sensor holes SH1 and SH2 may, for example, be two in number as shown in FIG. 1, but the embodiments of this specification are not limited thereto. For example, a single sensor hole may be provided. The two sensor holes SH1 and SH2 may be provided for the arrangement of an infrared sensor and a camera sensor, respectively; however, the embodiments of this specification are not limited thereto configuration. The sensor non-display area NDA_S may be disposed between the sensor holes SH1 and SH2 and the display area DA. The sensor non-display area NDA_S may completely surround the sensor holes SH1 and SH2. No pixels PX may be arranged in the sensor non-display area NDA_S. In some embodiments, an optical area may be disposed instead of the sensor holes SH1 and SH2. Pixels PX may be disposed in the optical area, but the number of pixels PX per unit area of the optical area may be less than the number of pixels PX per unit area of the display area DA.

A gate driving unit GIP (e.g., a circuit) may be arranged in the non-display area NDA located on each of one side and the other side of the display area DA in the first direction DR1. A low-potential voltage line VSSL may be disposed outside the gate driving unit GIP in the non-display area NDA. For example, as shown in FIG. 1, the low-potential voltage line VSSL may extend from a flexible printed circuit board FPCB, pass through a sub-region SR and a bending region BR, and be positioned outside the gate driving unit GIP in the non-display area NDA while surrounding the display area DA.

The non-display area NDA located on the opposite side of the display area DA in the second direction DR2 may extend further in the second direction DR2 from the central portion of that side of the display area DA. The width in the first direction DR1 of the non-display area NDA, which extends further in the second direction DR2 from the central portion of the opposite side of the display area DA in the second direction DR2, may be smaller than the width in the first direction DR1 of the non-display area NDA adjacent to the opposite side of the display area DA in the second direction DR2.

The display device 1 may include a main region MR, a sub-region SR, and a bending region BR between the main region MR and the sub-region SR. The display area DA and the non-display area NDA surrounding the display area DA on all four sides may form the main region MR, while the portion extending further in the second direction DR2 from the central portion of the other side of the display area DA may constitute the bending region BR and the sub-region SR. The bending region BR may be positioned between the sub-region SR and the main region MR. The sub-region SR may include a first pad area PA1 and a second pad area PA2 located at the opposite end of the sub-region SR in the second direction DR2. The display device 1 may further include a data driver DIC and a printed circuit board FPCB. The data driving unit DIC may be placed in the first pad area PA1, and the flexible printed circuit board FPCB may be attached to the second pad area PA2. The first pad area PA1 and the second pad area PA2 may each include a number of pads that connect the data driving unit DIC and the flexible printed circuit board FPCB. The data driving unit DIC may, for example, be provided in the form of a driving chip IC, but is not limited thereto. In an embodiment, the data driving unit DIC is arranged in a chip-on-plastic method, directly mounted on the display panel 100, but is not limited thereto, and may also be arranged in a chip-on-glass or chip-on-film method.

The display panel 100 according to an embodiment may further include a crack detection pattern CSP surrounding the low-potential voltage line VSSL. The crack detection pattern CSP may be arranged to completely surround the display area DA, as shown in FIG. 1. For example, the crack detection pattern CSP may be placed on the outer side of the low-potential voltage line VSSL. However, the embodiments of this specification are not limited thereto, and the crack detection pattern CSP may not be partially disposed in the non-display area NDA on the opposite side of the display area DA in the second direction DR2.

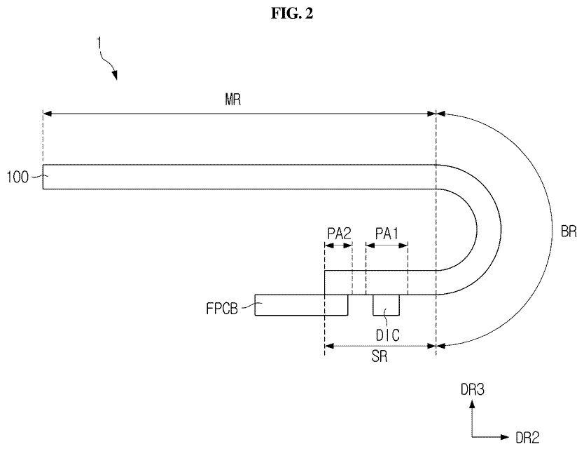

FIG. 2 is a cross-sectional view illustrating a bent state of the display panel in FIG. 1 according to an embodiment.

Referring to FIG. 2, the bending region BR of the display panel 100 of the display device 1 according to an embodiment may be bent in the thickness direction (or the third direction DR3). Through this, the main region MR and the sub-region SR may overlap in the thickness direction. The display panel 100 may be bent such that the bottom surface of the main region MR and the top surface of the sub-region SR face each other. A flexible printed circuit board FPCB may be attached to the end of the sub-region SR.

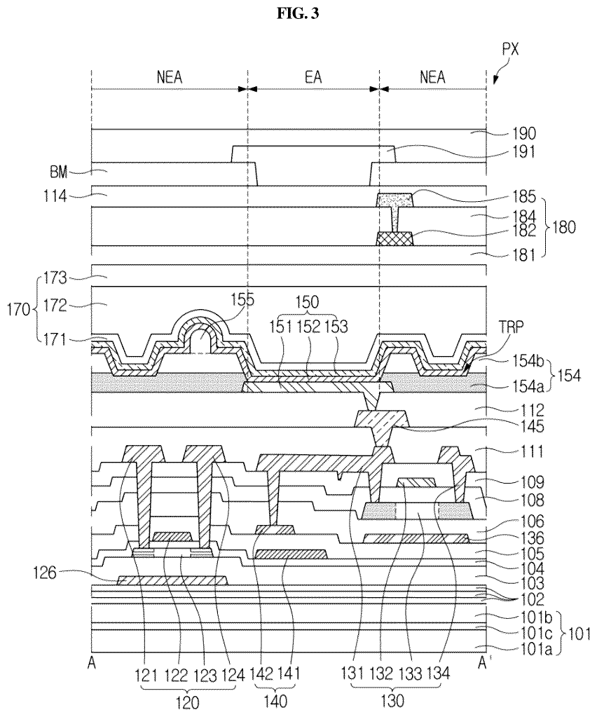

FIG. 3 is a cross-sectional view taken along line A-A′ of FIG. 1 according to an embodiment.

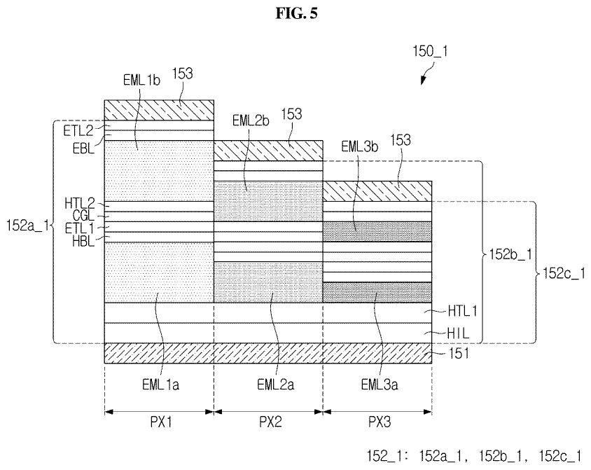

Referring to FIG. 3, the display panel 100 may include a substrate 101, a buffer layer 102, a first thin-film transistor 120, a second thin-film transistor 130, a storage electrode 140, a light emitting layer 150, an encapsulation layer 170, a touch layer 180, and an upper organic layer 190. FIG. 5 illustrates a cross-section of a sub-pixel of one of the pixels PX.

The substrate 101 may include one or more plastic materials. For example, the substrate 101 may be a multi-substrate including a plurality of plastic materials such as polyimide, but is not limited thereto. For example, the substrate 101 may include a first substrate portion 101a including an organic material, a second substrate portion 101b including an organic material, and a third substrate portion 101c including an inorganic material, but the embodiments of this specification are not limited thereto.

A buffer layer 102 may be disposed on the substrate 101. The buffer layer 102 may minimize or delay the diffusion of moisture or oxygen that penetrates into the substrate 101. The buffer layer 102 may be formed by alternately stacking silicon nitride SiNx and silicon oxide SiOx at least once, but is not limited thereto.

A first light-shielding layer 126 may be disposed on the buffer layer 102. The first light-shielding layer 126 may prevent or at least reduce light from passing through the first semiconductor layer 123 of the first thin-film transistor 120. For example, the first semiconductor layer 123 may be disposed to overlap with the first light-shielding layer 126. The first light-shielding layer 126 may be a single layer or a multilayer formed of any one of or alloys of molybdenum (Mo), aluminum (Al), chromium (Cr), nickel (Ni), neodymium (Nd), and copper (Cu), but is not limited thereto.

The first insulating layer 103 may be disposed on the first light-shielding layer 126. The first insulating layer 103 may prevent a short circuit between the components of the first thin-film transistor 120 and the first light-shielding layer 126. The first insulating layer 103 may be formed of the same material as the buffer layer 102, but is not limited thereto. For example, the first insulating layer 103 may be made of an inorganic material such as silicon nitride (SiNx) or silicon oxide (SiOx), but is not limited thereto.

A first thin-film transistor 120 may be disposed on the first insulating layer 103. The first thin-film transistor 120 may include a first source electrode 121, a first gate electrode 122, a first semiconductor layer 123, and a first drain electrode 124.

The first semiconductor layer 123 may be disposed on the first insulating layer 103. The first semiconductor layer 123 may include a metal oxide semiconductor such as indium-gallium-zinc oxide (IGZO), or a silicon-based semiconductor material such as amorphous silicon or polycrystalline silicon, but is not limited thereto. The first semiconductor layer 123 may include a channel region, a source region, and a drain region.

The polycrystalline semiconductor layer may have a higher mobility than the amorphous semiconductor layer and oxide semiconductor layer, which can result in lower energy consumption and improved reliability compared to the amorphous semiconductor layer and the oxide semiconductor layer. Therefore, the driving transistor may be formed using a polycrystalline semiconductor layer.

A second insulating layer 104 may be disposed on the first semiconductor layer 123. The second insulating layer 104 may be made of the same material as the first insulating layer 103 and may prevent short circuits between the first semiconductor layer 123 and other components of the first thin-film transistor 120.

A first gate electrode 122 may be disposed on the second insulating layer 104. The first gate electrode 122 may be arranged to overlap with the channel region of the first semiconductor layer 123, positioned on the second insulating layer 104. The first gate electrode 122 may be arranged as a single layer or multiple layers, including materials such as molybdenum (Mo), copper (Cu), titanium (Ti), aluminum (Al), chromium (Cr), gold (Au), nickel (Ni), neodymium (Nd), or their compounds. The first gate electrode 122 may be arranged along with a gate line.

A third insulating layer 105 may be disposed on the first gate electrode 122. The third insulating layer 105 may be made of the same material as the first insulating layer 103 or the second insulating layer 104.

A first source electrode 121 and a first drain electrode 124 may be disposed on the third insulating layer 105.

The first source electrode 121 and the first drain electrode 124 may be electrically connected to the first semiconductor layer 123 through contact holes. The first source electrode 121 and the first drain electrode 124 may be made of a metal material. For example, the first source electrode 121 and the first drain electrode 124 may be a single layer or multiple layers made of any one of molybdenum (Mo), aluminum (Al), chromium (Cr), gold (Au), titanium (Ti), nickel (Ni), neodymium (Nd), copper (Cu), or alloys thereof, but are not limited thereto.

The first source electrode 121 and the first drain electrode 124 may be arranged along with the data line. For example, the data line may be made of the same material as the first source electrode 121 and the first drain electrode 124, and may be formed in the same layer, but is not limited thereto.

The storage electrode 140 may be disposed apart from the first thin-film transistor 120. The storage electrode 140 may include a first storage electrode 141 and a second storage electrode 142.

The first storage electrode 141 may be disposed in the same layer as the first gate electrode 122 and made of the same material, but is not limited thereto.

The second storage electrode 142 may be disposed on the first storage electrode 141. The second storage electrode 142 may be disposed on the third insulating layer 105, and a capacitance may be formed between the first storage electrode 141 and the second storage electrode 142, with the third insulating layer 105 serving as a dielectric. The second storage electrode 142 may be made of the same material as the first storage electrode 141, but is not limited thereto.

The second thin-film transistor 130 may be disposed spaced apart from the first thin-film transistor 120 and the storage electrode 140. The second thin-film transistor 130 may include a second source electrode 131, a second gate electrode 132, a second semiconductor layer 133, and a second drain electrode 134.

The second light-shielding layer 136 may be disposed in the same layer as the second storage electrode 142.

The second light-shielding layer 136 may prevent or at least reduce light from reaching the second semiconductor layer 133, similar to the first light-shielding layer 126, thereby extending the lifespan of the second thin-film transistor 130. For example, the second semiconductor layer 133 may be disposed overlapping the second light-shielding layer 136.

The fourth insulating layer 106 may be disposed on the second light-shielding layer 136. The fourth insulating layer 106 may be made of the same material as the first insulating layer 103, the second insulating layer 104, or the third insulating layer 105, but is not limited thereto.

The second semiconductor layer 133 may be disposed on the fourth insulating layer 106. The second semiconductor layer 133 may include a source region, a drain region, and a channel region between the source and drain regions.

The second semiconductor layer 133 may include a metal oxide semiconductor such as indium-gallium-zinc oxide), an amorphous silicon, or a silicon-based semiconductor material such as polycrystalline silicon, but is not limited thereto.

The fifth insulating layer 108 may be disposed on the second semiconductor layer 133. The fifth insulating layer 108 may be formed of the same material as the first insulating layer 103, the second insulating layer 104, the third insulating layer 105, or the fourth insulating layer 106, but is not limited thereto.

The second gate electrode 132 may be disposed on the fifth insulating layer 108.

The second gate electrode 132 may be made of the same material as the first gate electrode 122. For example, the second gate electrode 132 may be formed as a single layer or a multilayer including molybdenum (Mo), copper (Cu), titanium (Ti), aluminum (Al), chromium (Cr), gold (Au), nickel (Ni), neodymium (Nd), or their compounds, but is not limited thereto.

The sixth insulating layer 109 may be disposed on the second gate electrode 132. The sixth insulating layer 109 may be formed of the same material as the first insulating layer 103, the second insulating layer 104, the third insulating layer 105, the fourth insulating layer 106, or the fifth insulating layer 108, but is not limited thereto.

The first source electrode 121, the first drain electrode 124, the third storage electrode 143, the second source electrode 131, and the second drain electrode 134 may be disposed on the sixth insulating layer 109.

The second source electrode 131 and the second drain electrode 134 may be formed of the same material as the first source electrode 121 and the first drain electrode 124, and may be disposed in the same layer. For example, the second source electrode 131 and the second drain electrode 134 may be a single layer or a multilayer made of any one of molybdenum (Mo), aluminum (Al), chromium (Cr), gold (Au), titanium (Ti), nickel (Ni), neodymium (Nd), and copper (Cu), or alloys thereof, but are not limited thereto. The second source electrode 131 may be electrically connected to the second storage electrode 142.

The first thin-film transistor 120 may be a switching transistor, and the second thin-film transistor 130 may be a driving transistor, but the embodiments are not limited thereto.

The first source electrode 121 and the first drain electrode 124 may have a first protective layer 111 disposed thereon.

The first protective layer 111 may flatten the upper part of the first thin-film transistor 120 and protect the first thin-film transistor 120. The first protective layer 111 may be made of an organic material. For example, the first protective layer 111 may be formed of an organic material such as acrylic resin, epoxy resin, phenolic resin, polyamide resin, or polyimide resin, but is not limited thereto.

The second protective layer 112 may be disposed on the first protective layer 111. The second protective layer 112 may be formed of the same material as the first protective layer 111, but is not limited thereto.

A connection electrode 145 may be disposed between the first protective layer 111 and the second protective layer 112.

The connection electrode 145 may electrically connect the second thin-film transistor 130 and the light-emitting layer 150. The connection electrode 145 may be formed of the same material as the first source electrode 121 and the first drain electrode 124 but is not limited thereto.

The connection electrode 145 may be a single layer or a multilayer made of any one of molybdenum (Mo), aluminum (Al), chromium (Cr), gold (Au), titanium (Ti), nickel (Ni), neodymium (Nd), and copper (Cu), or alloys thereof, but is not limited thereto.

The light-emitting layer 150 may be disposed on the second protective layer 112. The light-emitting layer 150 may include a first electrode 151, an organic layer 152, and a second electrode 153. A third protective layer may be further disposed on the second protective layer 112, but the embodiments of this specification are not limited thereto. When the third protective layer is further disposed, an additional connection electrode similar to the connection electrode may be disposed.

The first electrode 151 may be disposed on the second protective layer 112. The first electrode 151 may be electrically connected to the first thin-film transistor 120 through a contact hole formed in the second protective layer 112. The first electrode 151 may be a reflective electrode that reflects light, but is not limited thereto. The first electrode 151 may include a stacked structure of aluminum (Al) and titanium (Ti) (Ti/Al/Ti), a stacked structure of aluminum (Al) and ITO (ITO/Al/ITO), or a high-reflectivity metal material such as an APC alloy, and may be formed as a single layer or a multilayer, but is not limited thereto.

The organic layer 152 may be disposed on the first electrode 151. The organic layer 152 may include one or more light-emitting structures (or light-emitting elements) stacked on the first electrode 151 in the order of a hole transport layer and an electron transport layer, or in the reverse order. The organic layer 152 may be an organic light-emitting layer, an inorganic light-emitting layer, a quantum dot light-emitting layer, a micro light-emitting diode, or a micro-mini light-emitting diode, but is not limited thereto. For example, the display panel 100 according to an embodiment of this specification, the organic layer 152 may include an organic light-emitting layer. The organic layer 152 may include a red light-emitting layer, a green light-emitting layer, and a blue light-emitting layer.

A second electrode 153 may be disposed on the organic layer 152. The second electrode 153 may be a transparent electrode that transmits light, but is not limited thereto. For example, the second electrode 153 may include a transparent conductive material such as indium tin oxide (ITO) or indium zinc oxide (IZO), or a metal that transmits visible light.

A bank 154 may be disposed to expose the first electrode 151. The bank 154 may define an opening (or emissive area EA) of a sub-pixel and may be disposed to cover an edge portion of the first electrode 151. Each sub-pixel may include a red emissive area, a green emissive area, and a blue emissive area. For example, a sub-pixel may be defined as a pixel, but the terminology is not limited thereto.

The bank 154 may include a first bank 154a and a second bank 154b disposed on the first bank 154a. The first bank 154a may be a black bank including a black-based material, and the second bank 154b may include a transparent-based material. The second bank 154b may include the same material as the spacer 155 and may be formed through a halftone mask or a slit, but the embodiments of this specification are not limited thereto. A bank 154 may be disposed to expose the first electrode 151. Meanwhile, the bank 154 may have a separation portion recessed in a thickness direction. That is, the bank 154 may include a separation portion, and the separation portion may include a trench portion TRP as shown in FIG. 3. In the trench portion TRP, all of the second bank 154b and a part of the first bank 154a may be recessed, but the embodiments of this specification are not limited thereto, and only all of the second bank 154b may be recessed, or only a part of the second bank 154b may be recessed.

The organic layer 152 has an advantage of improving lateral leakage current because a current path is lengthened through the trench portion TRP.

A spacer 155 may be further disposed on the bank 154.

An encapsulation layer 170 may be disposed on the bank 154 or the light-emitting layer 150. The encapsulation layer 170 may include one or more insulating layers. For example, the encapsulation layer 170 may include a first encapsulation layer 171, a second encapsulation layer 172 located on top of the first encapsulation layer 171, and a third encapsulation layer 173 located on top of the second encapsulation layer 172. The encapsulation layer 170 may include one or more inorganic material layers and one or more organic material layers. For example, the first encapsulation layer 171 and the third encapsulation layer 173 may include an inorganic material, and the second encapsulation layer 172 may include an organic material.

A touch buffer layer 181 may be disposed on the encapsulation layer 170. For example, the touch buffer layer 181 may be disposed on the third encapsulation layer 173. The touch buffer layer 181 may be made of the same material as the buffer layer 102. A first touch conductive layer may be disposed on the touch buffer layer 181. A touch insulating layer 184 may be disposed on the first touch conductive layer. The touch insulating layer 184 may prevent a short circuit between touch electrodes. The touch insulating layer 184 may include an organic material or an inorganic material. In FIG. 5, the touch insulating layer 184 is illustrated as including an organic material, but the embodiments of this specification are not limited thereto. A second touch conductive layer may be disposed on the touch insulating layer 184.

The first touch conductive layer may include a second touch electrode 182, and the second touch conductive layer may include a first touch electrode 185.

The second touch electrode 182 may be electrically connected to the first touch electrode 185 through a contact hole formed in the touch insulating layer 184.

The first touch electrode 185 and the second touch electrode 182 may include metal materials. For example, the first touch conductive layer and the second touch conductive layer may be formed of titanium (Ti), nickel (Ni), aluminum (Al), or an alloy thereof, and may be formed as a triple layer such as titanium (Ti)/aluminum (Al)/titanium (Ti), but are not limited thereto.

A filter insulating layer 114 may be disposed on the touch layer 180, and a black matrix BM may be disposed on the filter insulating layer 114. A color filter 191 may be disposed on the black matrix BM. The color filter 191 may include a red color filter, a green color filter, or a blue color filter, but the embodiments of this specification are not limited thereto. The color filter 191 may overlap with the first electrode 151.

In FIG. 5, the separation distance between the black matrices BM at both ends of the color filter 191 is illustrated as being smaller than the separation distance between the first banks 154a at both ends of the first electrode 151 positioned below, but the embodiments of this specification are not limited thereto, and the separation distance between the black matrices BM at both ends of the color filter 191 may be larger than the separation distance between the first banks 154a at both ends of the first electrode 151 positioned below.

An upper organic layer 190 may be disposed on the color filter 191, but the embodiments of this specification are not limited thereto.

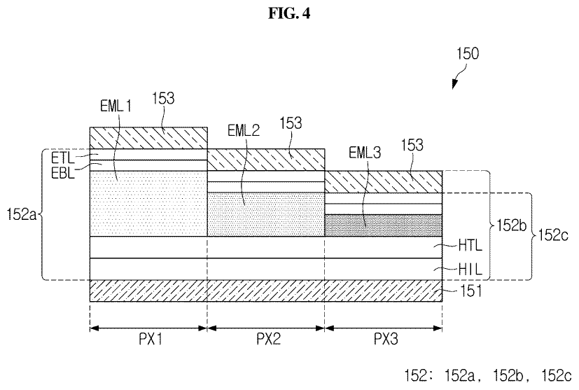

FIG. 4 is a detailed cross-sectional view of the lighting-emitting layer of FIG. 3 according to one embodiment.

Referring to FIG. 4, the light-emitting layer 150 may extend across a first sub-pixel PX1, a second sub-pixel PX2, and a third sub-pixel PX3. The pixel PX of FIG. 3 may include a plurality of sub-pixels PX1 to PX3.

The thickness of the light-emitting layer 150 may differ in each sub-pixel PX1, PX2, and PX3, but the embodiments of this specification are not limited thereto, and the thickness of the light-emitting layer 150 in each sub-pixel PX1, PX2, and PX3 may also be the same.

The organic layer 152 may include a first organic layer 152a disposed in the first sub-pixel PX1, a second organic layer 152b disposed in the second sub-pixel PX2, and a third organic layer 152c disposed in the third sub-pixel PX3. The light-emitting layers EML1, EML2, and EML3 in the respective organic layers 152a, 152b, and 152c may be physically separated, but the lower and upper layers of the light-emitting layers EML1, EML2, and EML3 may be integrally formed across the sub-pixels PX1, PX2, and PX3. The light-emitting layers EML1, EML2, and EML3 may differ in thickness. For example, the thickness of the first light-emitting layer EML1 may be the largest, followed by the second light-emitting layer EML2, and the thickness of the third light-emitting layer EML3 may be the smallest, but the embodiments of this specification are not limited thereto.

The hole injection layer HIL may be disposed on the first electrode 151. The hole injection layer HIL may be positioned between the first electrode 151 and the light-emitting layers EML1, EML2, and EML3. The hole injection layer HIL may be integrally formed across the sub-pixels PX1, PX2, and PX3. For example, the hole injection layer HIL may be made of a hole injection material selected from substances such as MTDATA, CuPc, TCTA, NPB (NPD), HATCN, TDAPB, PEDOT/PSS, F4TCNQ, N-(biphenyl-4-yl)-9,9-dimethyl-N-(4-(9-phenyl-9H-carbazole-3-yl)phenyl)-9H-fluorene-2-amine, but the embodiments of this specification are not limited thereto.

The hole transport layer HTL may be disposed on the hole injection layer HIL. The hole transport layer HTL may be positioned between the hole injection layer HIL and the light-emitting layers EML1, EML2, and EML3. The hole transport layer HTL may be integrally formed across the sub-pixels PX1, PX2, and PX3. The hole transport layer HTL may include one or more selected from the group consisting of arylamine-based compounds such as NPB (N,N′-naphthyl-N,N′-phenyl benzidine), TPD (N,N′-bis-(3-methylphenyl)-N,N′-bis-(phenyl)-benzidine), PPD, TTBND, FFD, p-dmDPS, TAPC; starburst aromatic amines such as TCTA, PTDATA, TDAPB, TDBA, 4-a, TCTA; spiro and ladder-type materials such as Spiro-TPD, Spiro-mTTB, Spiro-2; and NPD (N,N′-dinaphthyl-N,N′-diphenyl benzidine), s-TAD, and MTDATA (4,4′,4″-Tris(N-3-methylphenyl-N-phenyl-amino)-triphenylamine), but the embodiments of this specification are not limited thereto.

The light-emitting layers EML1, EML2, and EML3 may be disposed on the hole transport layer HTL. The first sub-pixel PX1 may have the first light-emitting layer EML1, the second sub-pixel PX2 may have the second light-emitting layer EML2, and the third sub-pixel PX3 may have the third light-emitting layer EML3.

The light-emitting layers EML1, EML2, and EML3 may differ in thickness. For example, the first light-emitting layer EML1 may have a thickness of 60 to 80 nm, the second light-emitting layer EML2 may have a thickness of 30 nm to 50 nm, and the third light-emitting layer EML3 may have a thickness of 10 nm to 30 nm, but the embodiments of this specification are not limited thereto.

The first light-emitting layer EML1, the second light-emitting layer EML2, and the third light-emitting layer EML3 may include materials that emit light in the visible light spectrum by combining holes and electrons, which are transported separately.

An electron blocking layer EBL may be disposed on each of the light-emitting layers EML1, EML2, and EML3. The electron blocking layer EBL may be integrally disposed across the sub-pixels PX1, PX2, and PX3.

An electron transport layer ETL may be disposed on the electron blocking layer EBL. The electron transport layer ETL may be integrally disposed across the sub-pixels PX1, PX2, and PX3. The electron transport layer ETL may be composed of anthracene derivatives and lithium quinolate (Liq), or may include materials selected from oxadiazole, triazole, phenanthroline, benzoxazole, benzthiazole, or benzimidazole (for example, 2-[4-(9,10-Di-2-naphthalenyl-2-anthracenyl)phenyl]-1-phenyl-1H-benzimidazole), but the embodiments of this specification are not limited thereto.

The second electrode 153 may be disposed on the electron transport layer ETL.

FIG. 5 is a detailed cross-sectional view of the light-emitting layer according to an alternative embodiment.

Referring to FIGS. 4 and 5, the organic layer 152_1 may include a first organic layer 152a_1 disposed in the first sub-pixel PX1, a second organic layer 152b_1 disposed in the second sub-pixel PX2, and a third organic layer 152c_1 disposed in the third sub-pixel PX3. In this specification, as shown in FIG. 4 and FIG. 5, the light-emitting layer of the organic layer 152, 152_1 for each sub-pixel PX1, PX2, PX3 is illustrated as being formed in one stack or two stacks, but the embodiments of this specification are not limited thereto, and the light-emitting layer may be formed in three or more stacks.

The light-emitting layers in respective organic layers 152a_1, 152b_1, and 152c_1 may be physically separated, but the lower and upper layers of the light-emitting layers may be integrally formed across the sub-pixels PX1, PX2, and PX3. The light-emitting layers may differ in thickness. For example, the first light-emitting layer in the first sub-pixel may have the greatest thickness, followed by the second light-emitting layer in the second sub-pixel, with the third light-emitting layer in the third sub-pixel having the smallest thickness, but the embodiments of this specification are not limited thereto. Additionally, the light-emitting layers in each organic layer 152a_1, 152b_1, and 152c_1 may include two or more layers.

The hole injection layer HIL may be disposed on the first electrode 151. The hole injection layer HIL may be positioned between the first electrode 151 and the light-emitting layers EML1a, EML2a, and EML3a. The hole injection layer HIL may be integrally formed across the sub-pixels PX1, PX2, and PX3. For example, the hole injection layer HIL may be made of a hole injection material selected from substances such as MTDATA, CuPc, TCTA, NPB (NPD), HATCN, TDAPB, PEDOT/PSS, F4TCNQ, N-(biphenyl-4-yl)-9,9-dimethyl-N-(4-(9-phenyl-9H-carbazole-3-yl)phenyl)-9H-fluorene-2-amine, but the embodiments of this specification are not limited thereto.

The first hole transport layer HTL1 may be disposed on the hole injection layer HIL. The first hole transport layer HTL1 may be positioned between the hole injection layer HIL and the light-emitting layers EML1a, EML2a, and EML3a. The first hole transport layer HTL1 may be integrally formed across the sub-pixels PX1, PX2, and PX3. The first hole transport layer HTL1 may include one or more selected from the group consisting of arylamine-based compounds such as NPB (N,N′-naphthyl-N,N′-phenyl benzidine), TPD (N,N′-bis-(3-methylphenyl)-N,N′-bis-(phenyl)-benzidine), PPD, TTBND, FFD, p-dmDPS, TAPC; starburst aromatic amines such as TCTA, PTDATA, TDAPB, TDBA, 4-a, TCTA; spiro and ladder-type materials such as Spiro-TPD, Spiro-mTTB, Spiro-2; and NPD (N,N′-dinaphthyl-N,N′-diphenyl benzidine), s-TAD, and MTDATA (4,4′,4″-Tris(N-3-methylphenyl-N-phenyl-amino)-triphenylamine), but the embodiments of this specification are not limited thereto.

The light-emitting layers EML1a, EML2a, and EML3a may be disposed on the first hole transport layer HTL1. The first sub-pixel PX1 may have a first-first light-emitting layer EML1a disposed therein, the second sub-pixel PX2 may have a second-first light-emitting layer EML2a disposed therein, and the third sub-pixel PX3 may have a third-first light-emitting layer EML3a disposed therein. The light-emitting layers EML1a, EML2a, and EML3a may be identical to the respective light-emitting layers EML1, EML2, and EML3 in FIG. 4.

The light-emitting layers EML1a, EML2a, and EML3a may differ in thickness. For example, the first light-emitting layer EML1a may be formed with a thickness of 60 nm to 80 nm, the second light-emitting layer EML2a may be formed with a thickness of 30 nm to 50 nm, and the third light-emitting layer EML3a may be formed with a thickness of 10 nm to 30 nm, but the embodiments of this specification are not limited thereto.

A hole blocking layer HBL may be disposed on each of the light-emitting layers EML1a, EML2a, and EML3a. The hole blocking layer HBL may be integrally disposed across the sub-pixels PX1, PX2, and PX3.

The first electron transport layer ETL1 may be disposed on the hole blocking layer HBL. The first electron transport layer ETL1 may be integrally disposed across the sub-pixels PX1, PX2, and PX3. The first electron transport layer ETL1 may be composed of an anthracene derivative and lithium quinolate (Liq), or may include one or more selected from the group consisting of oxadiazole, triazole, phenanthroline, benzoxazole, benzthiazole, or benzimidazole (for example, 2-[4-(9,10-Di-2-naphthalenyl-2-anthracenyl)phenyl]-1-phenyl-1H-benzimidazole), but the embodiments of this specification are not limited thereto.

A common charge generation layer CGL may be disposed on the first electron transport layer ETL1. The common charge generation layer CGL may be disposed between the first electron transport layer ETL1 and the second hole transport layer HTL2. The common charge layer CGL may include a conductive material, but the embodiments of this specification are not limited thereto.

The second hole transport layer HTL2 may be disposed on the common charge layer CGL. The second hole transport layer HTL2 may be positioned between the hole blocking layer HBL and the light-emitting layers EML1b, EML2b, and EML3b. The second hole transport layer HTL2 may be integrally formed across the sub-pixels PX1, PX2, and PX3. The material of the second hole transport layer HTL2 may be the same as that of the first hole transport layer HTL1, but the embodiments of this specification are not limited thereto.

The light-emitting layers EML1b, EML2b, and EML3b may be disposed on the second hole transport layer HTL2. The first sub-pixel PX1 may have a first-second light-emitting layer EML1b disposed therein, the second sub-pixel PX2 may have a second-second light-emitting layer EML2b disposed therein, and the third sub-pixel PX3 may have a third-second light-emitting layer EML3b disposed therein. The light-emitting layers EML1b, EML2b, and EML3b may be identical to the respective light-emitting layers EML1a, EML2a, and EML3a.

The light-emitting layers EML1b, EML2b, and EML3b may differ in thickness. For example, the first light-emitting layer EML1b may be formed with a thickness of 60 nm to 80 nm, the second light-emitting layer EML2b may be formed with a thickness of 30 nm to 50 nm, and the third light-emitting layer EML3b may be formed with a thickness of 10 nm to 30 nm, but the embodiments of this specification are not limited thereto.

An electron blocking layer EBL may be disposed on each of the light-emitting layers EML1b, EML2b, and EML3b. The electron blocking layer EBL may be integrally disposed across the sub-pixels PX1, PX2, and PX3.

The second electron transport layer ETL2 may be disposed on the electron barrier layer EBL. The second electron transport layer ETL2 may be integrally disposed across the sub-pixels PX1, PX2, and PX3. The second electron transport layer ETL2 may be composed of anthracene derivatives and Liq lithium quinolate, or any one or more selected from the group consisting of oxadiazole, triazole, phenanthroline, benzoxazole, benzthiazole, or benzimidazole (for example, 2-[4-(9,10-Di-2-naphthalenyl-2-anthracenyl)phenyl]-1-phenyl-1H-benzimidazole), but the embodiments of this specification are not limited thereto.

A second electrode 153 may be disposed on the second electron transport layer ETL2.

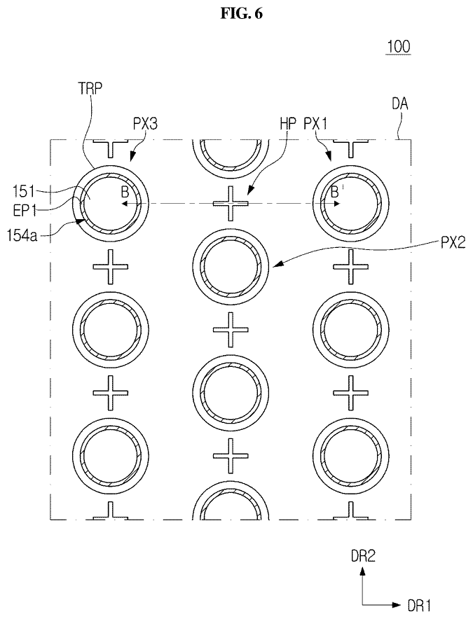

FIG. 6 is a plan view illustrating the arrangement of sub-pixels in the display area of FIG. 1 according to one embodiment.

Referring to FIG. 6, a display panel 100 according to an embodiment may include a plurality of sub-pixels PX1, PX2, and PX3. For example, the first sub-pixel PX1 may be a red sub-pixel, the second sub-pixel PX2 may be a green sub-pixel, and the third sub-pixel PX3 may be a blue sub-pixel, but the embodiments of this specification are not limited thereto. A boundary of each sub-pixel PX1, PX2, and PX3 may be a non-emissive area NEA (FIG. 3).

The first electrode 151 may be exposed by the banks 154a and 154b. For example, a planar shape of the first electrode 151 exposed by the bank 154a, 154b may be circular, but the embodiments of this specification are not limited thereto.

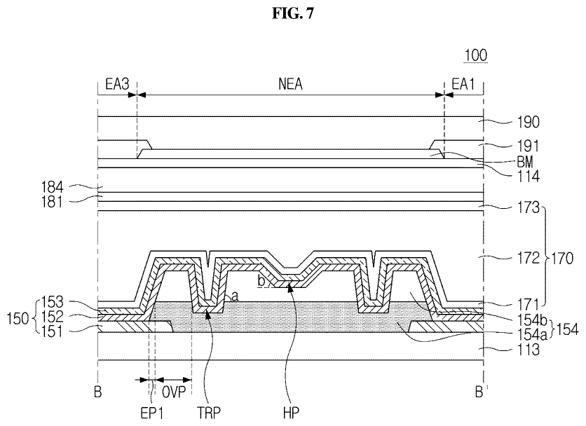

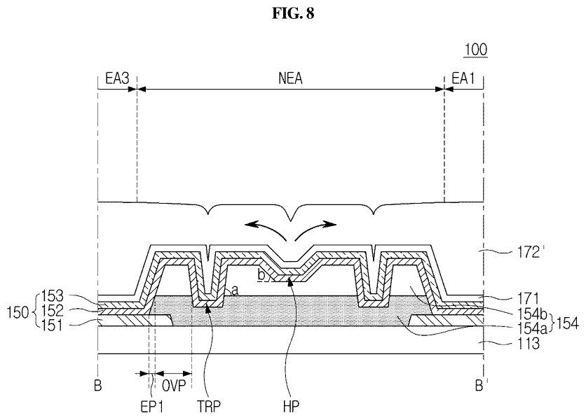

The first bank 154a may be exposed by the second bank 154b. Although FIG. 6 illustrates an area of the first bank 154a exposed by the second bank 154b, in practice, the first bank 154a may further include an area overlapping with the second bank 154b (the overlapping portion OVP of FIG. 7 and FIG. 8).

The first bank 154a may include a first exposed portion EP1 exposed by the second bank 154b. The first exposed portion EP1 may include a side surface of the bank 154 (FIG. 3). The first exposed portion EP1 may surround the first electrode 151 exposed by the banks 154a and 154b in a plan view. For example, the first exposed portion EP1 may completely surround the first electrode 151 exposed by the banks 154a and 154b in a plan view. The first exposed portion EP1 may overlap with the first electrode 151 while surrounding an area exposed by the bank 154a and 154b in a plan view.

The bank 154 may include the separation portion (or trench portion TRP) described above with reference to FIG. 3, and the trench portion TRP may surround the first exposed portion EP1 in a plan view. As shown in FIG. 6, the bank 154 may further include a groove portion HP. The groove portion HP may be disposed between adjacent sub-pixels PX1, PX2, and PX3.

For example, the groove portion HP may have a shape in which a first side extending along a first direction DR1 and a second side extending along a second direction DR2 cross each other (e.g., a cross shape), but the embodiments of this specification are not limited thereto.

FIG. 7 is a cross-sectional view taken along line B-B′ of FIG. 6 according to one embodiment.

Referring to FIG. 7, the bank 154 may include a trench portion TRP and a groove portion HP, and the groove portion HP may be disposed between adjacent trench portions TRP. The trench portion TRP may recess the bank 154 in a thickness direction. For example, the trench portion TRP may completely penetrate the second bank 154b and partially penetrate the first bank 154a. In contrast, the groove portion HP may partially penetrate the second bank 154b. A depth of the trench portion TRP may be greater than a depth of the groove portion HP.

Additionally, a slope a of an inner side surface of the bank 154 where the trench portion TRP is formed may be greater than a slope b of an inner side surface of the bank 154 where the groove portion HP is formed. For example, the slope a may be approximately 60 degrees or more, and the slope b may be approximately 30 degrees to approximately 50 degrees, but the embodiments of this specification are not limited thereto.

The depth of the trench portion TRP being greater than the depth of the groove portion HP, and the slope a of the inner side surface of the bank 154 where the trench portion TRP is formed being greater than the slope b of the inner side surface of the bank 154 where the groove portion HP is formed, are due to the different functions of the trench portion TRP and the groove portion HP. As described above, the trench portion TRP serves to separate the organic layer 152 in the non-emissive area NEA or to increase a current path of the organic layer 152, and thus, having a greater depth and a greater slope is preferable. In contrast, the groove portion HP, as described below, serves to improve the spreadability of the second encapsulation layer (or organic encapsulation layer), and thus, may not need to have the same depth and slope as the trench portion TRP.

FIG. 8 is a schematic diagram illustrating the improvement in the spreadability of the second encapsulation layer due to the groove portion according to FIG. 7 according to one embodiment.

Referring to FIGS. 7 and 8, a first encapsulation layer 171 may be disposed on the bank 154 including a groove portion HP. A second encapsulation layer 172′may be formed on the first encapsulation layer 171 and may include an organic material (or organic insulating material). The second encapsulation layer 172′applied to the emissive areas EA1 and EA3 may be difficult to spread into the non-emissive area NEA. In particular, as shown in FIG. 8, when an inner side surface (or side surface) of the first bank 154a and the second bank 154b is aligned to form a step, spreading beyond the step into the non-emissive area NEA may be very difficult, and the second encapsulation layer 172′ applied to the non-emissive area NEA may also be difficult to spread laterally.

However, in a display panel 100 according to an embodiment, the bank 154 includes the groove portion HP disposed between the trench portions TRP, thereby enabling the second encapsulation layer 172′ applied to the non-emissive area NEA to spread laterally.

Additionally, when a thickness of the second encapsulation layer 172′ is increased (or when an amount of the second encapsulation layer 172′ applied is increased), the second encapsulation layer 172′ may sufficiently spread into the non-emissive area NEA and the emissive areas EA1 and EA3, but the thickness of the second encapsulation layer 172′ may be applied downwardly. According to the display panel 100 of an embodiment, even when the thickness of the second encapsulation layer 172′ is applied downwardly, the spreadability of the second encapsulation layer 172′ may be improved.

Hereinafter, descriptions are provided of the display devices according to other embodiments. In the following embodiments, detailed explanations of the reference numerals or configurations already described with reference to FIGS. 1 to 8 will be omitted to avoid redundancy.

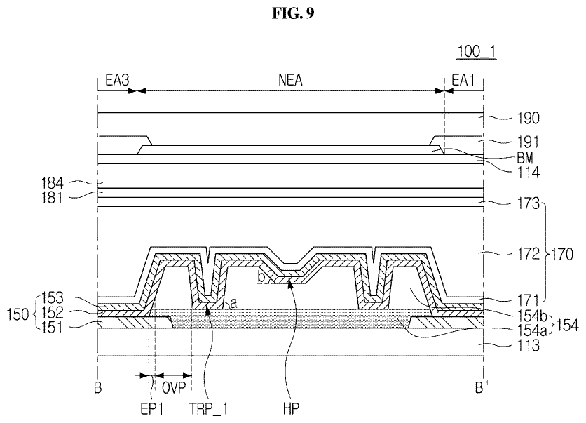

FIG. 9 is a cross-sectional view of a display device according to another embodiment.

Referring to FIG. 9, a trench portion TRP_1 of a display panel 100_1 of a display device according to this embodiment completely penetrates the second bank 154b and does not penetrate the first bank 154a at all, which differs from the display panel 100 according to FIG. 7.

An organic layer 152 in the trench portion TRP_1 may directly contact an upper surface of the first bank 154a.

Further details are as described above with reference to FIG. 7 and will be omitted hereinafter.

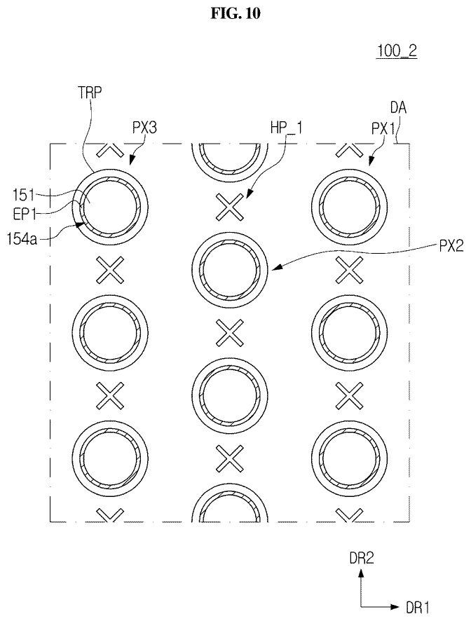

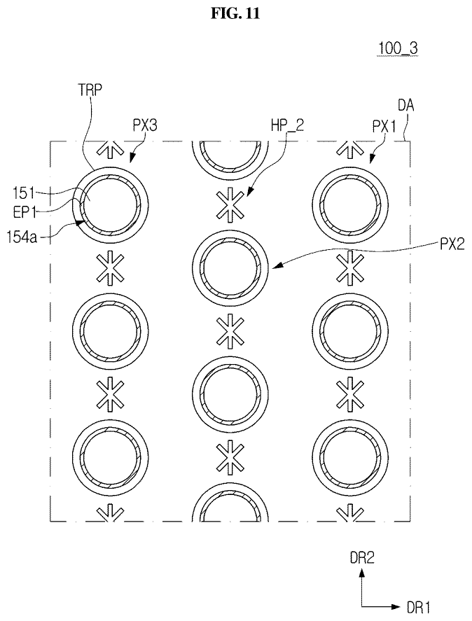

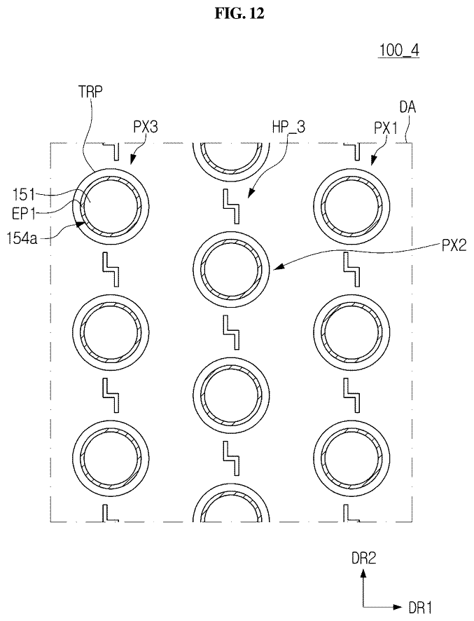

FIG. 10 is a plan view illustrating the arrangement of sub-pixels in a display area according to another embodiment. FIG. 11 is a plan view illustrating the arrangement of sub-pixels in a display area according to another embodiment. FIG. 12 is a plan view illustrating the arrangement of sub-pixels in a display area according to another embodiment.

Referring to FIGS. 10 to 12, a groove portion HP of FIG. 7 may have various shapes.

For example, a groove portion HP_1 of a display panel 100_2 according to FIG. 10 may have an X shape, a groove portion HP_2 of a display panel 100_3 according to FIG. 11 may have a shape in which a second side extending along a second direction DR2, a third side extending in a diagonal direction between a first direction DR1 and the second direction DR2, and a fourth side having a bilaterally symmetrical shape with respect to the second side based on a first side cross each other, and a groove portion HP_3 of a display panel 100_4 according to FIG. 12 may have a zigzag shape.

A shape of the groove portion according to embodiments is not limited to those illustrated in FIGS. 10 to 12 and may be modified as needed.

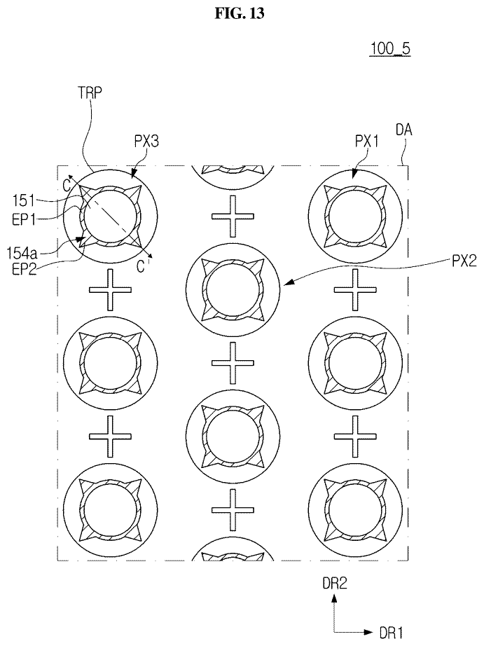

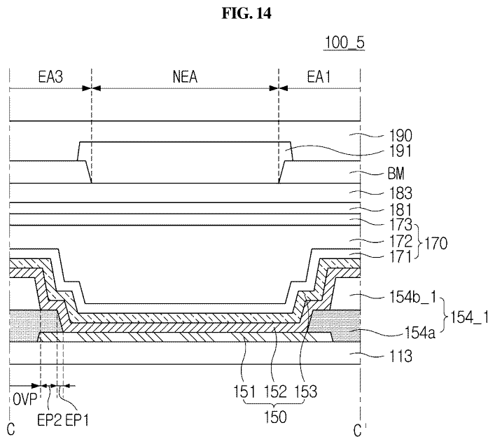

FIG. 13 is a plan view illustrating the arrangement of sub-pixels in a display area according to another embodiment. FIG. 14 is a cross-sectional view taken along line C-C′ of FIG. 13 according to one embodiment.

Referring to FIGS. 13 and 14, a bank 154_1 of a display panel 100_5 differs from the display panel 100 according to FIGS. 6 and 7 in including a second exposed portion EP2.

More specifically, the second exposed portion EP2 may protrude outward from a first exposed portion EP1 in a plan view. For example, the second exposed portion EP2 may be provided in plurality, and the plurality of second exposed portions EP2 may be disposed to be spaced apart in a plan view. In FIG. 13, for example, the second exposed portion EP2 is illustrated as protruding in a diagonal direction between a first direction DR1 and a second direction DR2, and four second exposed portions EP2 are illustrated, but the embodiments of this specification are not limited thereto. The second exposed portions EP2 may be spaced apart at equal intervals, but the embodiments of this specification are not limited thereto. In some embodiments, the second exposed portion EP2 may be disposed in the first direction DR1 or the second direction DR2.

For example, a planar shape of the second exposed portion EP2 may be substantially an equilateral triangle or a right triangle, but the embodiments of this specification are not limited thereto.

For example, an outline of a planar shape of the first bank 154a exposed by the second bank 154b may include at least one protrusion protruding outward. The protrusion may be the same as the second exposed portion EP2.

According to an embodiment, the banks 154a and 154b include a first bank 154a exposed by a second bank 154b and a second exposed portion EP2 disposed between the overlapping portion OVP (FIG. 14) and the first exposed portion EP1, with the second exposed portions EP2 arranged to be spaced apart from each other (with a protruding or angular structure applied to the bank), thereby improving the spreadability of the second encapsulation layer (or organic encapsulation layer). FIG. 13 illustrates a case in which a protruding structure is applied to the bank. In this specification, applying a protruding structure or an angular structure to the bank means that a shape formed by an outline of the first exposed portion EP1 and the second exposed portion EP2 of the bank has a protruding shape or an angular shape (or polygonal shape). In FIG. 13, a shape formed by an outline of the exposed portions EP1 and EP2 may be an angular shape.

FIG. 14 illustrates a cross-sectional shape of the banks 154a and 154b in which a second exposed portion EP2 is not disposed according to one embodiment.

As shown in FIGS. 13 and 14, the first bank 154a may cover a peripheral portion of a first electrode 151 and expose a central portion of the first electrode 151. A second bank 154b_1 may be disposed on the first bank 154a and overlap with the first bank 154a. The second bank 154b_1 may expose a portion of the first bank 154a. That is, the first bank 154a may include an overlapping portion OVP overlapping with the second bank 154b_1, and exposed portions EP1 and EP2 exposed by the second bank 154b_1. The exposed portions EP1 and EP2 may include a first exposed portion EP1 protruding from an end of the second bank 154b_1 toward the central portion of the first electrode 151, and a second exposed portion EP2 disposed between the first exposed portion EP1 and the overlapping portion OVP. The first exposed portion EP1 may include an inner side surface (or side surface) of the first bank 154a. An upper surface of the second exposed portion EP2 may directly contact an organic layer 152, and a side surface of the first exposed portion EP1 may directly contact the organic layer 152.

A second encapsulation layer 172 may be disposed on a first encapsulation layer 171 and include an organic insulating material. The second encapsulation layer 172, which includes an organic insulating material and has a large thickness, may be difficult to spread from an emissive area EA into a non-emissive area NEA when applied to the emissive area EA.

When a structure such as a protruding film is applied to a surface of the first encapsulation layer 171, surface tension between the second encapsulation layer 172 and the first encapsulation layer 171 may increase, allowing the second encapsulation layer 172 to overcome the step and spread, but in such a case, the role of the first encapsulation layer 171 in blocking external moisture may be diminished.

However, in the display panel 100_5 according to this embodiment, the first bank 154a may be exposed by the second bank 154b_1, and includes a second exposed portion EP2 disposed between the overlapping portion (see OVP in FIG. 14) and the first exposed portion EP1, with the second exposed portions EP2 arranged to be spaced apart from each other (with a protruding structure applied to the bank). That is, as shown in FIG. 14, by disposing an inner side surface of the first bank 154a and an inner side surface of the second bank 154b_1 to be spaced apart in a region where the second exposed portion EP2 is applied, a step between the inner side surfaces of the first and second banks 154a and 154b_1 may be mitigated. As a result, spreadability of the second encapsulation layer (or organic encapsulation layer) may be improved.

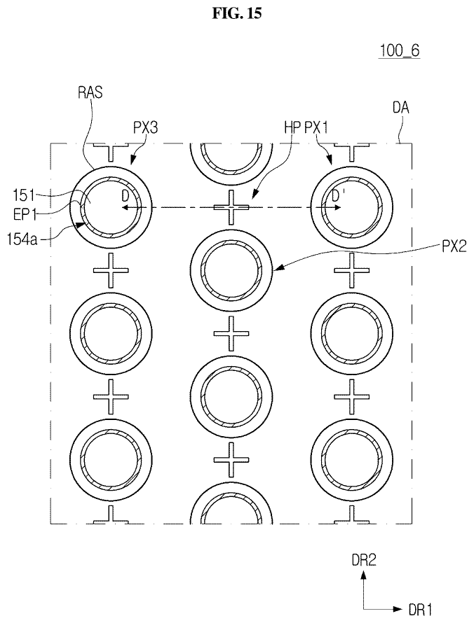

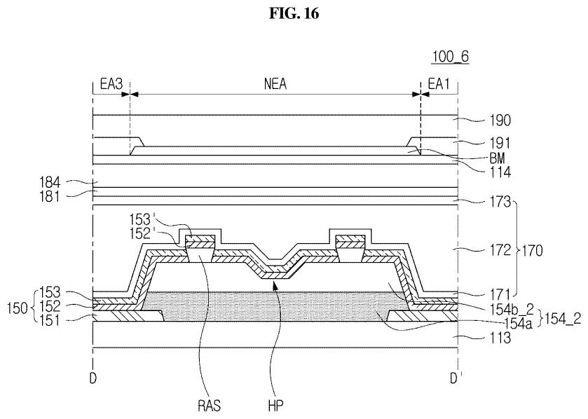

FIG. 15 is a plan view illustrating the arrangement of sub-pixels in a display area according to another embodiment. FIG. 16 is a cross-sectional view taken along line D-D′ of FIG. 15 according to one embodiment.

Referring to FIGS. 15 and 16, a display panel 100_6 according to this embodiment differs from the display panel 100 according to FIGS. 6 and 7 in including a separation portion RAS.

Referring to FIG. 16, the separation portion RAS according to this embodiment may be located on an upper surface of a second bank 154b_3 and disposed in a non-emissive area NEA. A bank 154b_2 according to this embodiment may not include a trench portion. The separation portion RAS serves to physically separate an organic layer 152, 152′ and a second electrode 153, 153′, respectively. That is, the organic layer 152 directly disposed on the upper surface of the second bank 154b_2 and the organic layer 152′ directly disposed on an upper surface of the separation portion RAS are physically separated, and the second electrode 153 on the organic layer 152 and the second electrode 153′ on the separation portion RAS may be physically separated.

The display panel 100_6 according to this embodiment may also apply a structure of the bank described with reference to FIGS. 13 and 14.

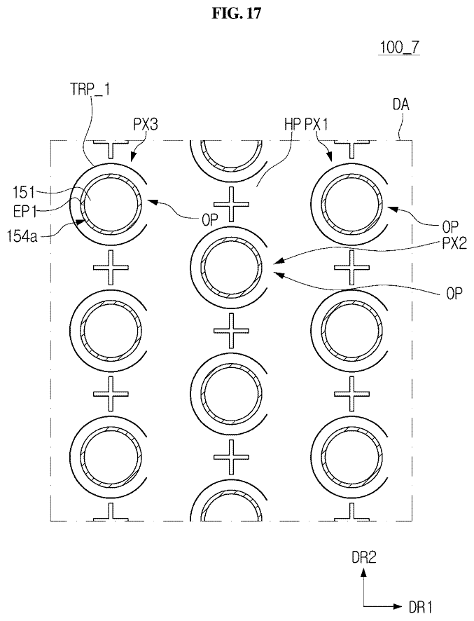

FIG. 17 is a cross-sectional view of a display device according to another embodiment.

Referring to FIG. 17, a separation portion RAS includes an open portion OP, and a first electrode 151 may be exposed in the open portion OP. A position and a number of the open portion OP are not limited to those in FIG. 17 and may be formed at various positions or have various numbers. The open portion OP may be located in a non-emissive area NEA.

Referring to FIGS. 16 and 17, a second electrode 153 receives a low-potential voltage from a low-potential voltage line and must be electrically connected across all sub-pixels PX1, PX2, and PX3. Thus, the separation portion RAS includes the open portion OP, thereby enabling the second electrode 153 inside the separation portion RAS to be physically connected to the second electrode 153 outside the separation portion RAS in a plan view.

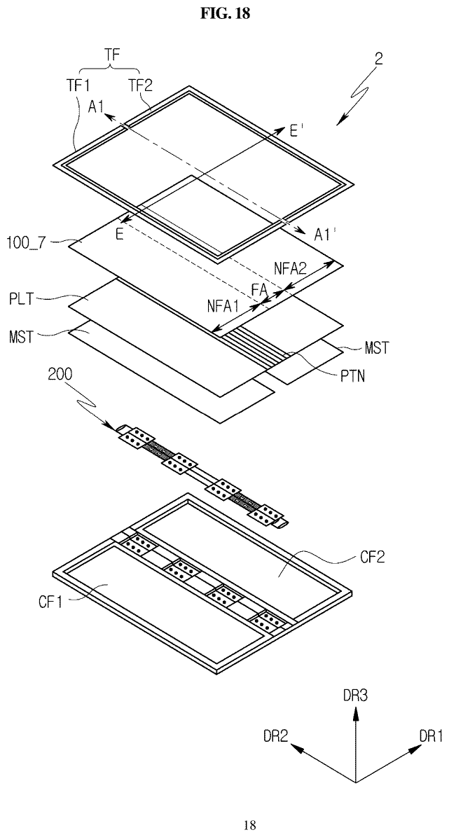

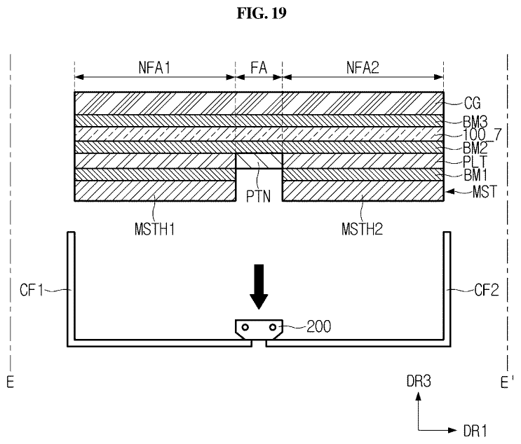

FIG. 18 is a perspective view of a display device according to another embodiment and FIG. 19 is a cross-sectional view taken along line E-E′ of FIG. 18 according to one embodiment.

The display device 2 according to the embodiment of FIGS. 18 and 19 differs from the display device 1 according to the embodiment of FIG. 1 in that it is a foldable display device.

In this specification, the folding axis A1 around which the display device 2 folds may be the same as the second direction DR2.

A top frame TF is arranged at the topmost part of the display device 2. The top frame TF includes a first top frame TF1 arranged on one side and a second top frame TF2 arranged on the opposite side, with respect to the folding axis A1. The top frame TF is positioned to cover the edges of the display panel 100_7. The top frame TF may protect the display panel 100_7 from external impacts. The top frame TF may form the bezel of the display device 2.

A cover layer CG may be placed beneath the top frame TF. The cover layer CG is arranged on top of the display panel 100_7.

By being placed on top of the display panel 100_7, the cover layer CG serves to protect the components placed underneath from external forces.

The panel assembly is arranged on the underside of the cover layer CG. The panel assembly includes the display panel 100_7 and a plate PLT. The display panel 100_7 may be substantially identical to one of the display panels 100 to 100_6 described above.

The plate PLT may be placed beneath the display panel 100_7 and include various plates that support the display panel 100_7. For example, one or more plates may include a back plate that supports the display panel 100_7, a top plate formed of SUS material placed beneath the back plate, a bottom plate formed of SUS material with patterns formed at the folding section placed beneath the top plate, a heat dissipation sheet for heat dissipation, and a middle plate covering the non-planar surface due to the various components of the hinge assembly.

The plate PLT may have a slit pattern PTN formed thereon. The slit pattern PTN may be formed at the position corresponding to the folding area FA of the display panel 100_7. The slit pattern PTN may be an etched section in the shape of a slit formed in the plate PLT. The plate PLT may be made of metal, such as SUS material, which may cause the plate PLT to encounter resistance when folding or unfolding due to the metal's strength. The slit pattern PTN may provide flexibility to the plate PLT. According to an embodiment of this specification, a slit pattern PTN in a plate PLT is formed in a second direction DR2 (or a long-axis direction) of a display panel 100_7 to face a first unfolding area NFA1 and a second unfolding area NFA2, but the embodiment is not limited thereto. For example, the slit pattern PTN may be formed in a first direction DR1 (or a short-axis direction) of the display panel 100_7 and disposed with the first unfolding area NFA1 and the second unfolding area NFA2 therebetween. That is, the display panel 100_7 may be folded in the first direction DR1 or folded in the second direction DR2.

A middle plate MST is placed beneath the panel assembly. The middle plate MST supports the components arranged there above. Additionally, beneath the middle plate MST, the hinge assembly 200 and the cover frame CF are placed, upper surfaces of which may be uneven. The middle plate MST may flatten the non-planar lower surface. The middle plate MST may be made of materials such as plastic, polyimide, or metal to enhance the rigidity of the display device 2. For example, the middle plate MST may include aluminum or SUS, but the embodiments of this specification are not limited to these materials.

The middle plate MST may include a first middle plate portion MSTH1 positioned in the first unfolding area NFA1 and a second middle plate portion MSTH2 positioned in the second unfolding area NFA2.

Below the panel assembly, the hinge assembly 200 is placed. The hinge assembly 200 is positioned at the lower part of the folding area FA. The hinge assembly 200 may have an elongated shape along the folding axis A1. The hinge assembly 200 may perform a folding motion with rotation on one side and the other side relative to the folding axis A1.

Beneath the hinge assembly 200, the cover frame CF is placed. A receiving groove may be formed on the upper surface of the cover frame CF, where a portion of the hinge assembly 200 may rest. The cover frame CF includes a first cover frame CF1 arranged on one side of the folding axis A1 and a second cover frame CF2 arranged on the opposite side. The cover frame CF may serve as a housing that defines the sides and rear of the display device 2. The cover frame CF can protect the display device 2 from external impacts. The cover frame CF can be coupled with the hinge assembly 200. Depending on the rotation of the cover frames CF1 and CF2, the folding and unfolding of the display device 2 may be implemented.

Additional coupling members BM1, BM2, and BM3 may be arranged between adjacent components MST, PLT, PNL, and CG to join the components together. The first coupling member BM1 may couple the middle plate sections MSTH1 and MSTH2 with the upper plate PLT in each unfolding area NFA1 and NFA2, the second coupling member BM2 may couple the plate PLT, PTN with the upper display panel 100_7, and the third coupling member BM3 may couple the display panel 100_7 with the cover layer CG.

The coupled plate PLT and middle plate MST may be seated on the cover frames CF1 and CF2. The display device 2 may perform folding and unfolding actions through the hinge assembly 200 placed on the cover frames CF1 and CF2.

Detailed explanations regarding the display panel 100_7, as have already been made, will be omitted.

The display device according to various embodiments of this specification may be described as follows.

A display device according to various embodiments of this specification includes a substrate including a display area having a plurality of sub-pixels including a first sub-pixel, a second sub-pixel, and a third sub-pixel, and a non-display area surrounding the display area, a first electrode disposed in each of the sub-pixels on the substrate, a bank disposed on the first electrode, positioned at a boundary between adjacent sub-pixels, covering a peripheral portion of an upper surface of the first electrode, and including a first bank on the first electrode and a second bank on the first bank, and an organic layer disposed on the first electrode and the bank, and extending across the plurality of sub-pixels, wherein the first bank includes an overlapping portion overlapping with the second bank, and a first exposed portion exposed by the second bank and including a side surface, and wherein the bank includes a groove portion formed to be recessed from an upper surface of the bank, and a separation portion surrounding the first exposed portion in a plan view.

The groove portion may be disposed between adjacent sub-pixels.

The separation portion may include a trench portion formed to be recessed from the upper surface of the bank, and a depth of the trench portion may be greater than a depth of the groove portion.

The trench portion may completely penetrate the second bank, and the groove portion may partially penetrate the second bank.

A slope of a side surface of the trench portion may be greater than a slope of a side surface of the groove portion.

The display device may further include a second electrode on the organic layer, and an encapsulation layer on the second electrode, the second encapsulation layer including an organic material, wherein the encapsulation layer may include a first encapsulation layer, a second encapsulation layer on the first encapsulation layer, and a third encapsulation layer on the second encapsulation layer.

The first bank may include an overlapping portion overlapping with the second bank, a first exposed portion exposed by the second bank and including a side surface, and a second exposed portion exposed by the second bank and disposed between the overlapping portion and the first exposed portion.

The second exposed portion may be provided in plurality, and in a plan view, adjacent ones of the plurality of second exposed portions may be spaced apart from each other.

A display device according to various embodiments includes a substrate having a display area with a plurality of sub-pixels including a first sub-pixel, a second sub-pixel, and a third sub-pixel, and a non-display area surrounding the display area, a first electrode disposed in each sub-pixel on the substrate, a bank positioned at a boundary between adjacent sub-pixels to cover a peripheral portion of an upper surface of the first electrode and including a first bank on the first electrode and a second bank on the first bank, a separation portion on an upper surface of the bank between adjacent sub-pixels, and an organic layer extending across the sub-pixels on the first electrode, the bank, and the separation portion, wherein the first bank includes an overlapping portion overlapping with the second bank and a first exposed portion exposed by the second bank and having a side surface, and the bank includes a groove portion recessed from an upper surface thereof.

The groove portion may be disposed between adjacent sub-pixels.

The separation portion may separate the organic layer, and the organic layer directly contacting the upper surface of the bank and the organic layer directly contacting an upper surface of the separation portion may be spaced apart from each other.

The display device may further include a second electrode on the organic layer, and an encapsulation layer on the second electrode, the second encapsulation layer including an organic material, wherein the encapsulation layer may include a first encapsulation layer, a second encapsulation layer on the first encapsulation layer, and a third encapsulation layer on the second encapsulation layer.

The separation portion may include an opening, and in a plan view, the second electrode inside the separation portion and the second electrode outside the separation portion may be connected at the opening.

The first bank may include an overlapping portion overlapping with the second bank, a first exposed portion exposed by the second bank and including a side surface, and a second exposed portion exposed by the second bank and disposed between the overlapping portion and the first exposed portion.

The second exposed portion may be provided in plurality, and in a plan view, adjacent ones of the plurality of second exposed portions may be spaced apart from each other.

The display device according to the embodiments is advantageous in absorbing external light incident beneath a bank by including a black-based material in the bank.

The display device according to the embodiments is advantageous in mitigating lateral leakage current between adjacent sub-pixels by separating an organic layer, which is integrally formed across all sub-pixels, using a trench formed in a protective layer.

The display device according to the embodiments is advantageous in improving the spreadability of a second encapsulation layer (or an organic encapsulation layer) by forming a groove in the bank at the boundary (or non-emissive region) between adjacent pixels.

The display device according to the embodiments is advantageous in improving the spreadability of the second encapsulation layer (or an organic encapsulation layer) by exposing a first bank through a second bank and providing a second exposed portion disposed between an overlapping portion and a first exposed portion, with the second exposed portions arranged to be spaced apart from each other (e.g., a protruding or angular structure applied to the bank).

The display device according to the embodiments is advantageous in improving the spreadability of the second encapsulation layer (or an organic encapsulation layer), even when the thickness of the second encapsulation layer (or the organic encapsulation layer) is reduced, by applying a protruding or angular structure to the bank.

The display device according to the embodiments is advantageous in improving the spreadability of the second encapsulation layer (or an organic encapsulation layer), even when the bank has a steep side slope, by applying a protruding or angular structure to the bank.

The display device according to the embodiments is advantageous in providing a low-reflection display device by absorbing external light incident beneath the bank.

The advantages achievable through this specification are not limited to the foregoing, and other advantages not explicitly described herein may be readily understood by those skilled in the art from the following description.

Although embodiments of this invention have been described above with reference to the accompanying drawings, it will be understood that the technical configuration of the invention described above can be implemented in other specific forms by those skilled in the art without changing the technical concept or essential features of the present invention. Therefore, it should be understood that the embodiments described above are exemplary and not limited in all respects. Furthermore, the scope of the present invention is defined by the claims set forth below, rather than the detailed description above. In addition, it should be construed that all modifications or variations derived from the meaning and scope of the claims and their equivalent concept are included within the scope of the invention.

### DESCRIPTION OF REFERENCE NUMERALS

1: display device
100, 100_1, 100_2, 100_3, 100_4, 100_5, 100_6, 100_7: display panel

What is claimed is:

1. A display device comprising:
a substrate including a display area having a plurality of sub-pixels including a first sub-pixel, a second sub-pixel, and a third sub-pixel, and a non-display area surrounding the display area;
a first electrode in each of the plurality of sub-pixels on the substrate;
a bank on the first electrode, positioned at a boundary between adjacent sub-pixels from the plurality of sub-pixels, and covering a peripheral portion of an upper surface of the first electrode, the bank including a first bank on the first electrode and a second bank on the first bank; and
an organic layer on the first electrode and the bank, the organic layer extending across the plurality of sub-pixels,
wherein the first bank includes an overlapping portion overlapping with the second bank and a first exposed portion exposed by the second bank and including a side surface,
wherein the bank includes a groove portion that is recessed from an upper surface of the bank and a separation portion surrounding the first exposed portion in a plan view.

2. The display device of claim 1, wherein the groove portion is between adjacent sub-pixels from the plurality of sub-pixels.

3. The display device of claim 1, wherein the separation portion comprises a trench portion that is recessed from the upper surface of the bank and a depth of the trench portion is greater than a depth of the groove portion.

4. The display device of claim 3, wherein the trench portion completely penetrates the second bank and the groove portion partially penetrates the second bank.

5. The display device of claim 3, wherein a slope of a side surface of the trench portion is greater than a slope of a side surface of the groove portion.

6. The display device of claim 1, further comprising:
a second electrode on the organic layer; and
an encapsulation layer on the second electrode, the encapsulation layer including an organic material,
wherein the encapsulation layer includes a first encapsulation layer, a second encapsulation layer on the first encapsulation layer, and a third encapsulation layer on the second encapsulation layer.

7. The display device of claim 1, wherein the first bank comprises:
a second exposed portion exposed by the second bank, the second exposed portion between the overlapping portion and the first exposed portion.

8. The display device of claim 7, wherein the second exposed portion is provided in plurality, and in the plan view, adjacent ones of the plurality of second exposed portions are spaced apart from each other.

9. The display device of claim 1, wherein the display device is a foldable display device.

10. The display device of claim 9, wherein the display device comprises a first side extending in a long-axis direction and a second side extending in a short-axis direction and is configured to be folded in the short-axis direction.

11. The display device of claim 1, wherein the bank comprises a black-based material.

12. A display device comprising:
a substrate including a display area having a plurality of sub-pixels including a first sub-pixel, a second sub-pixel, and a third sub-pixel, and a non-display area surrounding the display area;
a first electrode in each of the plurality of sub-pixels on the substrate;
a bank on the first electrode, positioned at a boundary between adjacent sub-pixels, and covering a peripheral portion of an upper surface of the first electrode, the bank including a first bank on the first electrode and a second bank on the first bank;
a separation portion on an upper surface of the bank between adjacent sub-pixels from the plurality of sub-pixels; and
an organic layer on the first electrode, the bank, and the separation portion, the organic layer extending across the plurality of sub-pixels,
wherein the first bank includes an overlapping portion overlapping with the second bank and a first exposed portion exposed by the second bank and including a side surface, and
wherein the bank includes a groove portion that is recessed from the upper surface of the bank.

13. The display device of claim 12, wherein the groove portion is between the adjacent sub-pixels.

14. The display device of claim 12, wherein the separation portion separates the organic layer, and the organic layer directly contacting the upper surface of the bank and the organic layer directly contacting an upper surface of the separation portion are spaced apart from each other.

15. The display device of claim 12, further comprising:
a second electrode on the organic layer; and
an encapsulation layer on the second electrode, the encapsulation layer including an organic material,
wherein the encapsulation layer includes a first encapsulation layer, a second encapsulation layer on the first encapsulation layer, and a third encapsulation layer on the second encapsulation layer.

16. The display device of claim 15, wherein the separation portion comprises an opening, and in a plan view, the second electrode inside the separation portion and the second electrode outside the separation portion are connected at the opening.

17. The display device of claim 12, wherein the first bank comprises:
a second exposed portion exposed by the second bank, the second exposed portion between the overlapping portion and the first exposed portion.

18. The display device of claim 17, wherein the second exposed portion is provided in plurality, and in a plan view, adjacent ones of the plurality of second exposed portions are spaced apart from each other.

19. The display device of claim 12, wherein the display device is a foldable display device and comprises a first side extending in a long-axis direction and a second side extending in a short-axis direction,
wherein the display device is configured to be folded in the short-axis direction.

20. The display device of claim 16, wherein the bank comprises a black-based material.
